(19) United States
(12) Patent Application Publication
(10) Pub. No.: US 2005/0116298 A1
(43) Pub. Date: Jun. 2, 2005

(54) MOS field effect transistor with small miller capacitance

(76) Inventor: Jenoe Tihanyi, Kirchheim (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/981,946

(22) Filed: Nov. 5, 2004

(30) Foreign Application Priority Data
Nov. 7, 2003 (DE) 103 51 932.7

(51) Int. Cl. H01L 29/76

(52) U.S. Cl. 257/372

(57) ABSTRACT

A MOS field effect transistor having a vertical source, drain and gate structure, the gate electrode of which has a dimensioning that determines the gate-drain capacitance (Miller capacitance) and provides a reduced capacitance.

### CROSS-REFERENCE TO RELATED APPLICATIONS

This Utility Patent Application claims priority to German Patent Application No. DE 103 51 932.7, filed on Nov. 7, 2003, which is incorporated herein by reference.

### FIELD OF THE INVENTION

The present invention relates to a MOS field effect transistor having at least one source zone of the first conduction type, at least one gate zone of the opposite conduction type to the first conduction type, and a drain zone of the first conduction type.

### BACKGROUND

When semiconductor zones of one conduction type are indiffused into a semiconductor substrate of the opposite conduction type, the dopant penetrates into the semiconductor substrate not only perpendicularly but also to a certain portion laterally under a doping window formed by the diffusion mask. As a result, the gate-drain capacitance, the so-called Miller capacitance, increases in the case of a MOS field effect transistor. As a result, the time constants are increased in integrated MOS circuits, which adversely affects the speed in the circuits.

### SUMMARY

Embodiments of the invention provide a transistor with a reduced Miller capacitance.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates one exemplary embodiment of a MOS field effect transistor with small Miller capacitance.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a MOS field effect transistor with small or reduced Miller capacitance.

In one embodiment a MOS field effect transistor of the invention includes means of a vertical sequence of source, gate and drain zones having a drain zone formed by a substrate, a gate zone formed in the substrate, and a source zone lying in the gate zone, and by means of a gate electrode having a part that is electrically active in the gate zone, the width of the part being determined by that part of the gate zone which is delimited by the source zone.

A development of the invention relates to a MOS field effect transistor having at least two gate zones and at least two source zones lying in the gate zones, the gate oxide being formed by an oxide layer and an oxide cushion that thickens the gate oxide layer and lies above the substrate between gate zones.

If, in accordance with a further embodiment of the invention, buried oxide layers are situated below the gate zones in the substrate, then the thickness of the dielectric of the Miller capacitance is increased, which leads to a further reduction of the capacitance value.

In accordance with a further embodiment of the invention, a conductive layer may be provided in the part of the gate electrode above the oxide cushion of the gate oxide, thereby achieving a low gate resistance. The conductive layer may comprise silicide or a metal, such as tungsten, for example.

A zone of the conduction type of the source zones may be provided in the substrate below the gate oxide for the purpose of setting the threshold voltage of the transistor.

The transistor structure may, in particular, also be provided on an insulation layer.

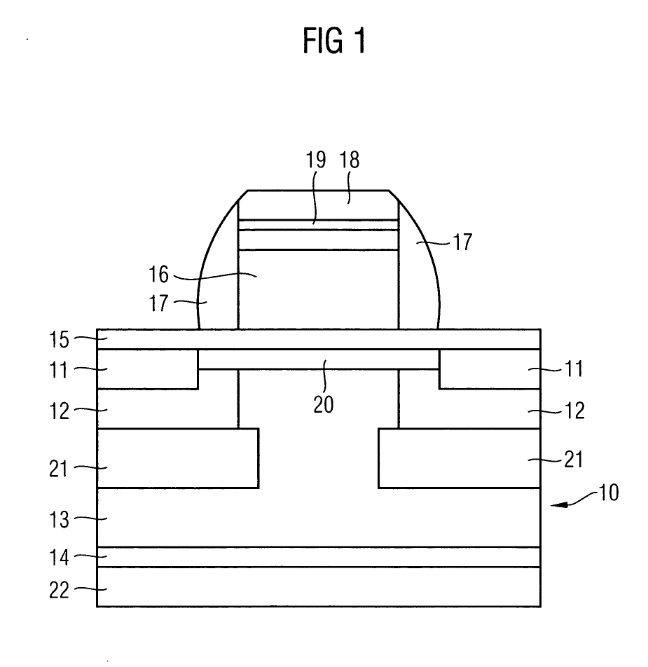

In one embodiment illustrated in FIG. 1, a transistor structure is formed in a semiconductor substrate 10 of one conduction type, for example n conduction type, which preferably comprises silicon and forms a drain zone 13. Gate zones 12 of the opposite conduction type, that is to say for example of the p conduction type, are formed in the substrate 10. Source zones 11 are provided in the gate zones 12, said source zones being highly doped n⁺ zones for the conduction types specified. The structure comprising source, gate and drain zones 11, 12, 13 constitutes a vertical MOS transistor structure.

In the substrate 10, provision is made of a highly doped zone 14 for making contact with the drain zone 13, which is n-conducting, that is to say an n⁺-type zone, in the exemplary embodiment.

On the substrate 10, provision is made of a gate oxide layer 15 and, above the latter, in the region defined by the gate zones 12, an oxide cushion 16. Silicon dioxide, for example, may be used for the layer 15 and the cushion 16.

Lying above the oxide cushion 16 is a gate electrode 17, 18, which is laterally delimited by the region between the edge of the gate zones 12 and the edge of the source zones 11. Said gate electrode 17, 18 is formed by highly doped n⁺-type polysilicon. The part 17 of the gate electrode 17, 18 which is electrically active in the gate zones 12 is thus laterally delimited by the edges of the source and gate zones 11, 12, as a result of which the area of the Miller capacitance between gate zone 12 and drain zone 13 and thus the value thereof are small. The part 17 of the gate electrode 17, 18 thus forms a part that determines a spacing, a so-called spacer.

A conductive layer 19 may be provided in the part 18 of the gate electrode 17, 18 that is situated above the oxide cushion 16, which conductive layer may comprise silicide or a metal, such as tungsten, for example. A low gate resistance can thus be realized.

In order to reduce the Miller capacitance further, buried oxide layers 21 may be provided below the gate zones 12. The thickness of the dielectric of the capacitance is thus increased, which results in the corresponding reduction of the value thereof.

The entire transistor structure may be provided on an insulation layer 22.

A zone 20 of the conduction type of the substrate 10 may be provided at the surface of the substrate 10 in the region of the source zones 11, as a result of which it is possible to set the threshold voltage of the MOS field effect transistor.

The fabrication of the MOS field effect transistor according to the invention proceeds from an n⁺-n-type epitaxial substrate 10, the contact-making zone 14 and the gate zone 13 thereby being formed. The buried oxide layers 21 are fabricated therein, as is described for example, in the published U.S. patent application Ser. No. US 2003/0151112 A1, incorporated herein by reference. The gate oxide layer 15 and the oxide cushion 16 are fabricated on the substrate thus patterned with the buried oxide layers 21. The gate zones 12 are implanted after the patterning of the oxide cushion 16. The gate electrode 17, 18 with the spacer 17 is then fabricated. The spacer 17 defines the channel zones in this case. The source zones 11 are then implanted. The zone 20 is also implanted. During the ion implantations for the zones 11, 12, 20, the oxide cushion 16 and the spacer 17 may serve as an ion implantation mask. The implanted doping distribution should not be diffused apart. Thus, in order that the implantation profiles are preserved, the implantation annealing should be effected by rapid thermal annealing. The contact-making is effected in a conventional manner either by means of metal or polysilicon, a multilayer structure also being possible. The entire structure may be constructed on the insulation layer 22. The dimensions are not of importance in this case. The lateral dimensions only at the edge are significant for the Miller capacitance. The drain drift zone may also be constructed on the compensation principle, that is to say comprise p-type and n-type regions arranged in a suitable manner.

In another embodiment, instead of silicon, it is also possible to use another semiconductor material, for example SiC or A III B V. Moreover, the conductivity types specified may also be respectively reversed.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A MOS field effect transistor comprising:
at least one source zone of a first conduction type;
at least one gate zone of an opposite conduction type to the first conduction type; and
a drain zone of the first conduction type,
wherein the source zones, gate zones and drains are configured in a vertical sequence having a drain zone formed by a substrate, a gate zone formed in the substrate, and a source zone lying in the gate zone, and a gate electrode having a part that is electrically active in the gate zone, the width of the part being determined by that part of the gate zone which is delimited by the source zone.

2. The transistor of claim 1, comprising:
at least two gate zones and at least two source zones lying in the gate zones.

3. The transistor of claim 1, wherein the gate oxide is formed by an oxide layer and an oxide cushion that thickens the gate oxide layer and lies above the substrate between gate zones.

4. The transistor of claims 1, comprising:
a buried oxide layer located below each gate zones.

5. The transistor of claim 1, comprising:
a conductive layer is provided in the part of the gate electrode above the oxide cushion of the gate oxide.

6. The transistor of claim 5, wherein he conductive layer is a silicide layer.

7. The transistor of claim 5, wherein the conductive layer is a metal layer.

8. The transistor of claim 7, wherein the metal layer is a tungsten layer.

9. The of transistor claim 1, comprising:
a zone of the conduction type of the source zones is provided in the substrate below the gate oxide.

10. The transistor of 1, comprising:
an insulation layer, wherein the source zone, the gate zone and the drain zone sequence is provided on an insulation layer.

11. A MOS field effect transistor comprising:
at least one source zone of a first conduction type;
at least one gate zone of the opposite conduction type to the first conduction type; and
a drain zone of the first conduction type,
wherein the source zone, the gate zone and the drain zone are configured in a vertical sequence having the drain zone formed by a substrate, the gate zone formed in the substrate, the source zone lying in the gate zone, and a gate electrode having a part that is electrically active in the gate zone, the width of said part being determined by that part of the gate zone which is delimited by the source zone, and wherein the electrically active part of the gate electrode is formed as a spacer that is horizontally delimited by the edges of the source zone and of the gate zone.

12. The transistor of claim 11, comprising:
at least two gate zones and at least two source zones lying in the gate zones, and wherein the gate oxide is formed by an oxide layer and an oxide cushion that thickens the gate oxide layer and lies above the substrate between gate zones.

13. The transistor of claims 11, comprising:
a buried oxide layer located below each gate zones.

14. The transistor of claim 11, comprising:
a conductive layer is provided in the part of the gate electrode above the oxide cushion of the gate oxide.

15. The transistor of claim 14, wherein he conductive layer is one of a silicide layer, a metal layer, or a tungsten layer.

16. The of transistor claim 11, comprising:
a zone of the conduction type of the source zones is provided in the substrate below the gate oxide.

17. The transistor of 16, comprising:
an insulation layer, wherein the source zone, the gate zone and the drain zone sequence are provided on an insulation layer.

18. A transistor comprising:
at least one source zone of a first conduction type;
at least one gate zone of the opposite conduction type to the first conduction type;
a drain zone of the first conduction type, wherein the source zone, the gate zone and the drain zone are configured in a vertical sequence having the drain zone formed by a substrate, the gate zone formed in the substrate, the source zone lying in the gate zone, and a gate electrode having a part that is electrically active in the gate zone, the width of said part being determined by that part of the gate zone which is delimited by the source zone, and wherein the electrically active part of the gate electrode is formed as a spacer that is horizontally delimited by the edges of the source zone and of the gate zone;
at least two gate zones and at least two source zones lying in the gate zones, and wherein the gate oxide is formed by an oxide layer and an oxide cushion that thickens the gate oxide layer and lies above the substrate between gate zones; and
a buried oxide layer located below each gate zones,
thereby providing a transistor with a reduced Miller capacitance

19. The transistor of claim 18, comprising:
a conductive layer is provided in the part of the gate electrode above the oxide cushion of the gate oxide.

20. A MOS field effect transistor comprising:
at least one source zone of a first conduction type;
at least one gate zone of the opposite conduction type to the first conduction type;
a drain zone of the first conduction type,
wherein the source zone, the gate zone and the drain zone are configured in a vertical sequence having the drain zone formed by a substrate, the gate zone formed in the substrate, the source zone lying in the gate zone;
gate electrode means having a part that is electrically active in the gate zone, the width of said part being determined by that part of the gate zone which is delimited by the source zone, and wherein the electrically active part of the gate electrode is formed as a spacer that is horizontally delimited by the edges of the source zone and of the gate zone.

21. The transistor of claim 20, comprising:
at least two gate zones and at least two source zones lying in the gate zones, and wherein the gate oxide is formed by an oxide layer and an oxide cushion that thickens the gate oxide layer and lies above the substrate between gate zones; and
a buried oxide layer located below each gate zones.
